(19) United States
(12) Patent Application Publication
(10) Pub. No.: US 2009/0014777 A1
(43) Pub. Date: Jan. 15, 2009

(54) Flash Memory Devices and Methods of Manufacturing the Same

(75) Inventors: Chun-Hyung Chung, Gyeonggi-do (KR); Seung-Hwan Lee, Gyeonggi-do (KR); Bong-Jin Kuh, Gyeonggi-do (KR); Sun-Jung Kim, Gyeonggi-do (KR); Hoon-Sang Choi, Seoul (KR); Sang-Wook Lim, Gyeonggi-do (KR); Young-Sun Kim, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/143,951

(22) Filed: Jun. 23, 2008

(30) Foreign Application Priority Data
Jul. 9, 2007 (KR) 10-2007-0068844

(51) Int. Cl. H01L 29/00; H01L 21/3205

(52) U.S. Cl. 257/321; 438/594; 257/E21.294; 257/E29.001

(57) ABSTRACT

Provided are flash memory devices. Embodiments of such devices may include a tunnel insulator formed on a substrate, a charge-storage layer formed on the tunnel insulator, a lower buffer layer formed on the charge-storage layer, a blocking layer formed on the lower buffer layer, and a first gate electrode formed on the blocking layer. Such devices may include second gate electrode formed on the first gate electrode, such that the lower buffer layer includes a silicon-free insulator, the blocking layer includes oxides or ternary lanthanum compounds, and

the oxides or ternary lanthanum compounds include lanthanide elements.

### CROSS REFERENCE TO RELATED APPLICATION

This application claims priority from Korean Patent Application No. 10-2007-0068844 filed on Jul. 9, 2007, in the Korean Intellectual Property Office, the disclosure of which is incorporated herein by reference in its entirety.

### BACKGROUND

The present invention relates to semiconductors, and, more particularly, to a flash memory devices and methods of manufacturing the same.

In general, flash memory devices may preserve information even when power is not supplied, have high integration and fast operation speed, and may write and erase information. As a result, flash memory devices may be desirable for use as non-volatile memory devices.

In a floating-gate-type flash memory device, the data retention may mean that charges stored in a floating gate may be maintained without leaking. In a charge-trap-type flash memory device, the data retention may mean that charges trapped in a charge trap layer may be maintained without leaking.

Another characteristic of the flash memory devices may be its ability to perform stable data writes (data programming/erasing characteristic). The data write (data P/E characteristic) means that in an operation mode in which information is written or corrected in a flash memory device, charges may be tunneled from a substrate or a channel region to a floating gate or a charge trap layer to store data. Further, the data write may mean that charges flow from the floating gate or the charge trap layer to the substrate or the channel region. In general, if the characteristics of an inter-gate insulator (inter-gate dielectric) in the floating-gate-typed flash memory device, or the characteristics of a blocking layer in the charge-trap-type flash memory device are good, the charges tunnel from a control gate electrode or the like, which may deteriorate the data write operation.

Since future flash memory devices may operate in a low voltage and current region, data retention and data write need to be improved.

### SUMMARY OF THE INVENTION

Some embodiments of the present invention include flash memory devices. Some embodiments of such devices may include a tunnel insulator on a substrate, a charge-storage layer on the tunnel insulator, a lower buffer layer on the charge-storage layer, and a blocking layer on the lower buffer layer. Embodiments of such devices may further include a first gate electrode on the blocking layer and a second gate electrode on the first gate electrode. In some embodiments, the lower buffer layer includes a silicon-free insulator, the blocking layer includes oxides or ternary lanthanum compounds, and the oxides or ternary lanthanum compounds include lanthanide elements.

In some embodiments, the lower buffer layer includes any one of HfO₂, ZrO₂, Sc₂O₃, and Al₂O₃. In some embodiments, the oxides or ternary lanthanum compounds further include any one of LaHfO₃, LaAlO₃, LaOₓ, DyScO₃, GdScO₃, Dy₂O₃, PrOₓ, and NdOₓ. Some embodiments include an upper buffer layer formed between the blocking layer and the first gate electrode. In some embodiments, the upper buffer layer includes any one of HfO₂, ZrO₂, Sc₂O₃, and Al₂O₃.

In some embodiments, the charge-storage layer includes an insulator that is formed of any one of SiₓN_{y}, SiₓO_{y}, HfO₂, ZrO₂, Ta₂O₅, HfAlO, HfZrO, HfSiO, AlN, and AlGaN. In some embodiments, the charge-storage layer includes a conductive silicon layer. In some embodiments, the first gate electrode includes a tantalum compound. In some embodiments, the second gate electrode includes conductive silicon. Some embodiments include an insulating capping layer formed on the second gate electrode.

Some embodiments of the present invention include methods of manufacturing a flash memory device. Some embodiments of such methods may include forming a tunnel insulator on a substrate, forming a charge-storage layer on the tunnel insulator, and forming a lower buffer layer that includes a silicon-free insulator on the charge-storage layer. Some embodiments may further include forming a blocking layer on the lower buffer layer, forming a first gate electrode on the blocking layer, and forming a second gate electrode on the first gate electrode. In some embodiments, the blocking layer includes oxides or ternary lanthanum compounds, and the oxides or ternary lanthanum compounds include lanthanide elements.

In some embodiments, the lower buffer layer includes any of HfO₂, ZrO₂, Sc₂O₃, and/or Al₂O₃. In some embodiments, the oxides or ternary lanthanum compounds include any of LaHfO₃, LaAlO₃, LaOₓ, DyScO₃, GdScO₃, Dy₂O₃, PrOₓ, and/or NdOₓ. Some embodiments may include forming an upper buffer layer between the blocking layer and the first gate electrode. In some embodiments, the upper buffer layer includes any of HfO₂, ZrO₂, SC₂O₃, and/or Al₂O₃.

In some embodiments, the charge-storage layer includes an insulating layer and any of SiₓN_{y}, SiₓO_{y}, HfO₂, ZrO₂, Ta₂O₅, HfAlO, HfZrO, HfSiO, AIN, and/or AlGaN. In some embodiments, the charge-storage layer includes a conductive silicon layer. In some embodiments, the first gate electrode includes a tantalum compound. In some embodiments, the second gate electrode includes conductive silicon. Some embodiments may include forming an insulating capping layer on the second gate electrode.

### BRIEF DESCRIPTION OF THE DRAWINGS

FIGS. 1A to 1C are schematic longitudinal sectional views illustrating charge-trap-type flash memory devices according to some embodiments of the invention.

FIGS. 2A to 2C are schematic diagrams illustrating flash memory devices that include floating gates according to some embodiments of the invention.

FIG. 3 is a graph illustrating a result that is obtained by experimentally measuring leakage current characteristics of charge-trap-type flash memory devices among flash memory devices according to some embodiments of the invention.

FIGS. 4A to 4C are graphs illustrating a result that is obtained by experimentally measuring the charge-trap characteristic of charge-trap layers of charge-trap-type flash memory devices among flash memory devices according to some embodiments of the invention.

FIGS. 5A to 5D are schematic diagrams illustrating operations for manufacturing a charge-trap-type flash memory device according to some embodiments of the invention.

### DETAILED DESCRIPTION

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present invention. In addition, as used herein, the singular forms “a”, “an” and “the” are intended to include the plural forms as well, unless the context clearly indicates otherwise. It also will be understood that, as used herein, the term “comprising” or “comprises” is open-ended, and includes one or more stated elements, steps and/or functions without precluding one or more unstated elements, steps and/or functions. The term “and/or” includes any and all combinations of one or more of the associated listed items.

It will also be understood that when an element is referred to as being “connected” to another element, it can be directly connected to the other element or intervening elements may be present. In contrast, when an element is referred to as being “directly connected” to another element, there are no intervening elements present. It will also be understood that the sizes and relative orientations of the illustrated elements are not shown to scale, and in some instances they have been exaggerated for purposes of explanation. Like numbers refer to like elements throughout.

In the figures, the dimensions of structural components, including layers and regions among others, are not to scale and may be exaggerated to provide clarity of the concepts herein. It will also be understood that when a layer (or layer) is referred to as being ‘on’ another layer or substrate, it can be directly on the other layer or substrate, or can be separated by intervening layers. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the present specification, data write may include both an operation for programming data in a flash memory device and an operation for erasing data from the flash memory device.

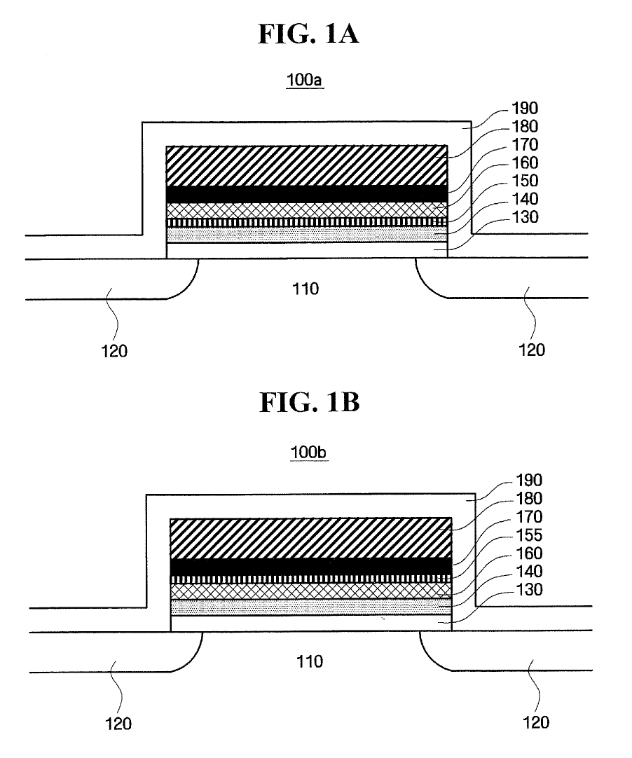

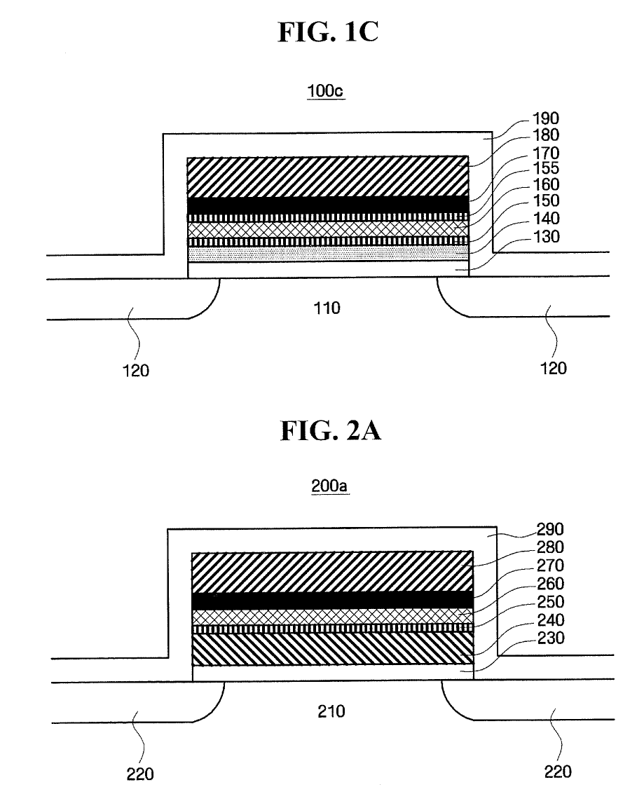

Reference is now made to FIGS. 1A to 1C, which are schematic longitudinal sectional views illustrating charge-trap-type flash memory devices according to embodiments of the invention. A charge-trap-type flash memory device 100a according to some embodiments of the invention includes junction regions 120 that may be formed in a substrate 110, a tunnel insulator 130 that may be formed on the substrate 110, a charge-storage layer 140 that may be formed on the tunnel insulator 130, a lower buffer layer 150 that may be formed on the charge-storage layer 140, a blocking layer 160 that may be formed on the lower buffer layer 150, a first gate electrode 170 that may be formed on the blocking layer 160, a second gate electrode 180 that may be formed on the first gate electrode 170, and/or a capping layer 190 that may cap the second gate electrode 180.

In the some embodiments, the flash memory device 100a may include a charge trap flash (CTF). That is, an insulator may be formed as the charge-storage layer 140.

In some embodiments, the substrate 110 may be a silicon substrate, a silicon-germanium substrate, an SOI (silicon on insulator) substrate or an SOS (silicon on sapphire) substrate.

The junction regions 120 may render the substrate 110 conductive, and may be formed by implanting elements of Group 3 or 5 of the Periodic Table of Elements in an ionic state.

In some embodiments, the tunnel insulator 130 is formed of a silicon oxide layer (SiₓO_{y} compound including SiO₂). When forming the tunnel insulator 130 using the silicon oxide layer, the tunnel insulator 130 may be formed by oxidizing the substrate 110 or depositing the silicon oxide layer on the substrate 110. In some embodiments, the tunnel insulator 130 may be formed by a variety of processes including thermally oxidizing the surface of the substrate 110, among others.

In some embodiments, the charge-storage layer 140 is formed of a silicon nitride layer (SiₓN_{y} compound including Si₃N₄). In some embodiments, the charge-storage layer 140 may be formed by using various insulating compounds, such as SiₓO_{y}, HfO₂, ZrO₂, Ta₂O₅, HfAlO, HfZrO, HfSiO, AlN, AlGaN, and/or the silicon nitride layer, among others.

The lower buffer layer 150 may be formed of a silicon-free insulator. Specifically, the lower buffer layer 150 may be formed of Al₂O₃, HfO₂, ZrO₂, or Sc₂O₃. In some embodiments, the lower buffer layer 150 may be formed of an aluminum oxide layer (for example, Al₂O₃). The lower buffer layer 150 may improve an effect of preventing charges from being tunneled between the gate electrode 170 and the charge-storage layer 140 during a programming or erasing operation of the flash memory device 100a.

In some embodiments, the lower buffer layer 150 may improve an interface characteristic between the blocking layer 160 (described in detail below) and the charge-storage layer 140, and reduce a leakage current. Accordingly, the lower buffer layer 150 may prevent charges from leaking into other layers from the charge-storage layer 140 and may prevent charges from being tunneled between the first and second gate electrodes 170 and 180 and the charge-storage layer 140. Therefore, the lower buffer layer 150 may improve the data retention and the data write of the flash memory device 100a.

In some embodiments, the blocking layer 160 may be formed of oxides and ternary compounds that contain lanthanide elements of the Periodic Table of Elements. Various compounds including LaHfO₃, LaAlO₃, LaOₓ, DyScO₃, GdScO₃, Dy₂O₃, PrOₓ, NdOₓ, and/or the like, may be used as the oxides or ternary compounds that contain the lanthanide elements.

The blocking layer 160 may prevent the charges from being tunneled between the gate electrodes 170 and 180 and the charge-storage layer 140. The blocking layer 160 may have a large energy band gap when a dielectric constant is high. In this regard, the blocking layer 160 may be formed of an insulator having a high dielectric constant so as to improve a function of the flash memory device 100a. That is, the case where the charges trapped in the charge-storage layer 140 hop an energy barrier of the blocking layer 160 and leak into the gate electrodes 170 and 180 may occur infrequently, which may improve data retention. Since it may be difficult for the charges to be tunneled between the gate electrodes 170 and 180 and the charge-storage layer 140, data-write operations may be improved.

In some embodiments, the blocking layer 160 may be formed of oxides and ternary compounds that contain lanthanide elements of the Periodic Table of Elements. In accordance with some embodiments, experiments performed using LaHfO₃ or LaAlO₃ included results that were substantially similar to each other for both LaHfO₃ and LaAlO₃. For reference, the oxides and the ternary compounds that contain lanthanide elements of the Periodic Table of Elements, such as LaHfO₃ or LaAlO₃ exemplified in some embodiments, may have a dielectric constant of about 20 and an energy gap of about 6.5 eV according to forming methods thereof.

In some embodiments, the blocking layer 160 may be formed by using ternary compounds that contain lanthanide elements having a high dielectric constant and a large energy gap. In some embodiments, the lower buffer layer 150 may be formed at the interface between the blocking layer 160 and the charge-storage layer 140. In some embodiments, the first gate electrode 170 can function as a diffusion barrier layer and/or a glue layer.

In some embodiments, the first gate electrode 170 may be formed of tantalum nitride layer (TaN). The first gate electrode 170 may be formed between the blocking layer 160 and the second gate electrode 180, and may improve adhesion between the blocking layer 160 and the second gate electrode 180 and interface resistance thereof. Since the first gate electrode 170 may have low resistance, it can improve the function of the flash memory device 100a. The first gate electrode 170 may be formed of tantalum nitride and/or other compounds.

In some embodiments, the second gate electrode 180 may be formed of a conductive silicon layer. The second gate electrode 180 may also be called TANOS (tantalum-alumina-nitride-oxide-silicon) or SONOS (silicon-oxide-nitride-oxide-silicon) according to whether the first gate electrode 170 exists. The structure and/or name, however, may be used for convenience and are not intended to limit the scope or spirit of the embodiments herein.

In some embodiments, the capping layer 190 may be formed of a single silicon oxide layer, a multi-layered insulator including a silicon oxide layer, and/or a multi-layered insulator including a silicon nitride layer.

The capping layer 190 may be formed in a shape in which it caps gate structures including, for example, a laminated structure of the tunnel insulator 130 and/or the second gate electrode 180. In a partial region, the capping layer 190 can extend to the junction regions 120. The junction regions 120 may be electrically connected to signal-transmitting lines (not shown) to transmit electric signals. As illustrated herein, some embodiments may provide that the capping layers may be formed over an entire surface of the gate structures and the junction regions.

Reference is now made to FIG. 1B, which is a flash memory device 100b according to some embodiments of the present invention. The flash memory device 100b may include junction regions 120 that are formed in a substrate 110, a tunnel insulator 130 that is formed on the substrate 110, a charge-storage layer 140 that is formed on the tunnel insulator 130, a blocking layer 160 that is formed on the charge-storage layer 140, an upper buffer layer 155 that is formed on the blocking layer 160, a first gate electrode 170 that is formed on the upper buffer layer 155, a second gate electrode 180 that is formed on the first gate electrode 170, and/or a capping layer 190 that caps the second gate electrode 180.

The flash memory device 100b as illustrated in FIG. 1B is different from the flash memory device 100a illustrated in FIG. 1A in that the lower buffer layer (refer to reference numeral 150 in FIG. 1A) is not formed and an upper buffer layer 155 is formed. In some embodiments, the upper buffer layer 155 may be formed of a silicon-free insulator. Specifically, the upper buffer layer 155 can be formed of Al₂O₃, HfO₂, ZrO₂, or Sc₂O₃. In some embodiments, the upper buffer layer 155 may be formed of an aluminum oxide layer (for example, Al₂O₃). The upper buffer layer 155 may include a function similar to that of the lower buffer layer 150 shown in FIG. 1A.

Reference is now made to FIG. 1C, which is a flash memory device 100c according to some embodiments of the present invention. Some embodiments include junction regions 120 that are formed in a substrate 110, a tunnel insulator 130 that is formed on the substrate 110, a charge-storage layer 140 that is formed on the tunnel insulator 130, a lower buffer layer 150 that is formed on the charge-storage layer 140, a blocking layer 160 that is formed on the lower buffer layer 150, an upper buffer layer 155 that is formed on the blocking layer 160, a first gate electrode 170 that is formed on the upper buffer layer 155, a second gate electrode 180 that is formed on the first gate electrode 170, and/or a capping layer 190 that caps the second gate electrode 180.

The flash memory device 100c as illustrated in FIG. 1C is different from the flash memory devices 100a and 100b as illustrated in FIGS. 1A and 1B, respectively, in that both the lower buffer layer 150 and the upper buffer layer 155 are formed. Accordingly, the flash memory device 100c according some embodiments illustrated in FIG. 1C can achieve the effect of improving the characteristics of some embodiments of the flash memory devices 100a and 100b as illustrated in FIGS. 1A and 1B, respectively.

For example, since the lower buffer layer 150 that is formed between the charge-storage layer 140 and the blocking layer 160 can improve the interface characteristics between the charge-storage layer 140 and the blocking layer 160, the data retention and/or the data write operation may be improved.

Since the upper buffer layer 155 that is formed between the blocking layer 160 and the first and second gate electrodes 170 and 180 can improve the interface characteristics between the blocking layer 160 and the first and second gate electrodes 170 and 180, the data retention and/or the data write operation may be improved.

In some embodiments according to FIGS. 1A-1C, the first gate electrode 170 may not be formed. In particular, in some embodiments, when the upper buffer layer 155 is formed, the first gate electrode 170 may not be formed. The first gate electrode 170 may improve the interface characteristics between the blocking layer 160 and the second gate electrode 180. However, when the upper buffer layer 155 is formed, the upper buffer layer 155 may improve the interface characteristics between the blocking layer 160 and the second gate electrode 180. In this regard, it may be possible to achieve at least one of functions of the first gate electrode 170. Further, when the first gate electrode 170 is indispensable to the flash memory device, the upper buffer layer 155 may not be formed, as discussed in detail below.

In some embodiments, the charge-storage layer 140 may include quantum dots. Quantum dots are regions where charges may be further trapped in the charge-storage layer 140 in order to increase the amount of charge trapped in the charge-storage layer 140. In some embodiments, quantum dots may be formed of conductive materials, such as silicon, germanium, or metal. In some embodiments, quantum dots may be formed by inserting island dots during a process where the charge-storage layer 140 is formed.

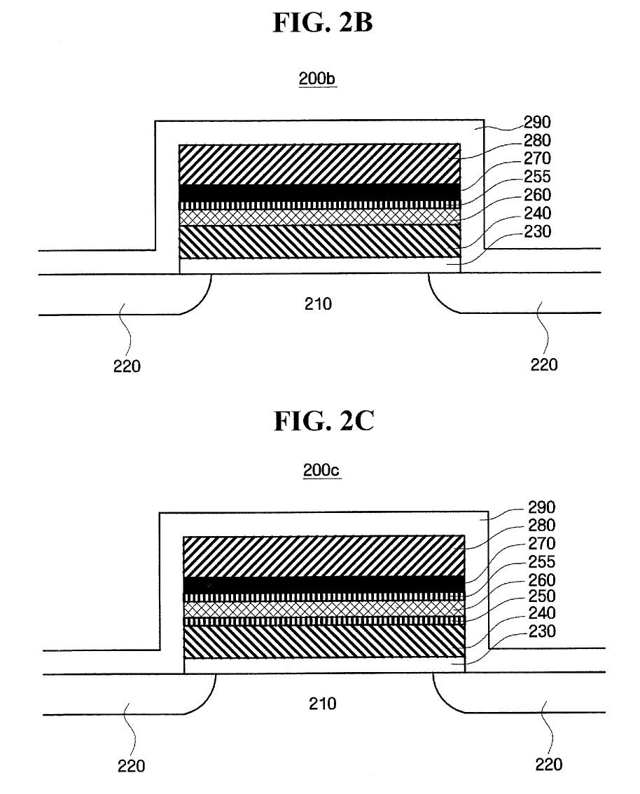

Reference is now made to FIGS. 2A to 2C, which are schematic diagrams illustrating flash memory devices that include floating gates according to some embodiments of the present invention. Referring to FIG. 2A, a flash memory device 200a may include junction regions 220 that are formed in a substrate 210, a tunnel insulator 230 that is formed on the substrate 210, a charge-storage layer 240 that is formed on the tunnel insulator 230, a lower buffer layer 250 that is formed on the charge-storage layer 240, a blocking layer 260 that is formed on the lower buffer layer 250, a first control gate electrode 270 that is formed on the blocking layer 260, a second control gate electrode 280 that is formed on the first control gate electrode 270, and/or a capping layer 290 that caps the second control gate electrode 280.

In some embodiments, charges pass through the tunnel insulator 230, such that the charges are tunneled from the substrate 210 or channel regions (not shown) of the junction regions 220 to the charge-storage layer 240 in a write operation state. In some embodiments, the charge-storage layer 240 may be a floating gate and may be formed of conductive silicon. The conductivity may be provided by implanting elements of Group 3 and/or 5 of the Periodic Table of Elements into the silicon layer in an ionic state. The charge-storage layer 240, that is, the floating gate, can store information by accumulating charges and having a polarity.

The lower buffer layer 250 may be formed between the charge-storage layer 240 and the blocking layer 260 and may improve the interface characteristics between the charge-storage layer 240 and the blocking layer 260. Further, the lower buffer layer 250 may intercept a leakage current and improve a function of the flash memory device 200a. Some embodiments provide that the lower buffer layer 250 may be formed of a silicon-free insulator. In some embodiments, the lower buffer layer 250 may be formed of oxides, including, for example, aluminum oxides (Al₂O₃).

In some embodiments, the blocking layer 260 may be formed of oxides and ternary compounds that contain lanthanide elements of the Periodic Table of Elements. Specifically, the blocking layer 260 may be formed of various compounds, such as LaHfO₃, LaAlO₃, LaOₓ, DyScO₃, GdScO₃, Dy₂O₃, PrOₓ, and NdOₓ.

The first control gate electrode 270 can function as a diffusion barrier layer and/or a glue layer. In some embodiments, the first control gate electrode 270 may be formed of a tantalum-containing compound, for example, a tantalum nitride layer (TaN). The first control gate electrode 270 may have the same function as the first gate electrode 170 that is used in some embodiments of the present invention.

The lower buffer layer 250 and the blocking layer 260 may be formed between the charge-storage layer 240 and the control gates 270 and 280, and may prevent the charges from being tunneled and/or leaking between the charge-storage layer 240 and the control gates 270 and 280.

Referring to FIG. 2B, a flash memory device 200b according some embodiments includes junction regions 220 that is formed in a substrate 210, a tunnel insulator 230 that is formed on the substrate 210, a charge-storage layer 240 that is formed on the tunnel insulator 230, a blocking layer 260 that is formed on the charge-storage layer 240, an upper buffer layer 255 that is formed on the blocking layer 260, a first gate electrode 270 that is formed on the upper buffer layer 255, a second gate electrode 280 that is formed on the first gate electrode 270, and/or a capping layer 290 that caps the second gate electrode 280.

The flash memory device 200b as shown in FIG. 2B may be different from the flash memory device 200a shown in FIG. 2A in that the lower buffer layer (250 in FIG. 2A) is not formed and the upper buffer layer 255 is formed. In some embodiments, the upper buffer layer 255 may be formed of a silicon-free insulator. In some embodiments, the upper buffer layer 255 may be formed of an aluminum oxide layer. The upper buffer layer 255 may provide a function that is similar to that of the lower buffer layer 250 shown in FIG. 2A.

Referring to FIG. 2C, a flash memory device 200c according to some embodiments may include junction regions 220 that are formed in a substrate 210, a tunnel insulator 230 that is formed on the substrate 210, a charge-storage layer 240 that is formed on the tunnel insulator 230, a lower buffer layer 250 that is formed on the charge-storage layer 240, a blocking layer 260 that is formed on the lower buffer layer 250, an upper buffer layer 255 that is formed on the blocking layer 260, a first gate electrode 270 that is formed on the upper buffer layer 255, a second gate electrode 280 that is formed on the first gate electrode 270, and/or a capping layer 290 that caps the second gate electrode 280.

The flash memory device 200c shown in FIG. 2C may be different from the flash memory devices 200a and 200b shown in FIGS. 2A and 2B, respectively, in that both the lower buffer layer 250 and the upper buffer layer 255 are formed. Therefore, the flash memory device 200c shown in FIG. 2C may achieve the effect of improving characteristics of the flash memory devices 200a and 200b as shown in FIGS. 2A and 2B, respectively.

That is, the lower buffer layer 250 that is formed between the charge-storage layer 240 and the blocking layer 260 may improve the interface characteristics between the charge-storage layer 240 and the blocking layer 260, and thus the data retention and/or the data write may be improved.

Further, the upper buffer layer 255 that is formed between the blocking layer 260 and the gate electrodes 270 and 280 may improve the interface characteristics between the blocking layer 260 and the gate electrodes 270 and 280, and thus the data retention and/or the data write operation may be improved.

In some embodiments of the invention, the first control gate electrode 270 may not be formed. In particular, when the upper buffer layer 255 is formed, the first control gate electrode 270 may not be formed. The first control gate electrode 270 may provide a function of improving the interface characteristics between the blocking layer 260 and the second gate electrode 280. However, when the upper buffer layer 255 is formed, the upper buffer layer 255 may improve the interface characteristics between the blocking layer 260 and the second control gate electrode 280. In this regard, it is possible to achieve at least one of the functions of the first control gate electrode 270. Further, when the first control gate electrode 270 is included in the flash memory device, the upper buffer layer 255 may not be formed, as discussed in detail below.

As explained by the present inventors, when the blocking layer is formed of an insulator that contains lanthanum and has a high dielectric constant, it may be possible to securely prevent the charges from being tunneled from the gate electrodes to the charge-storage layer. However, the blocking layer easily reacts with silicon. In this regard, when the charge-storage layer is formed of a compound that contains silicon (for example, silicon nitride), a defect may occur at the interface between the blocking layer and the charge-storage layer. For example, when a silicon atom or the like diffuses and/or moves for a reaction, voids and/or spikes may be formed at the interface, thereby causing a strong electric field and/or charge leakage. As explained by the present inventors, elements may become electrically and physically abnormal and may cause an erroneous operation.

In flash memory devices according to some embodiments herein, a silicon-free insulator may be formed between oxides and ternary compounds that contain lanthanide elements of the Periodic Table of Elements, and silicon or a silicon-containing compound. Accordingly, the physical and electrical characteristics of the insulators may be improved. In some embodiments herein, the charge trap layer 140 and the floating gate 240 may provide a function of storing information. In this regard, the charge trap layer 140 and the floating gate 240 may be referred to as the charge-storage layers 140 and 240 for the convenience of explanation.

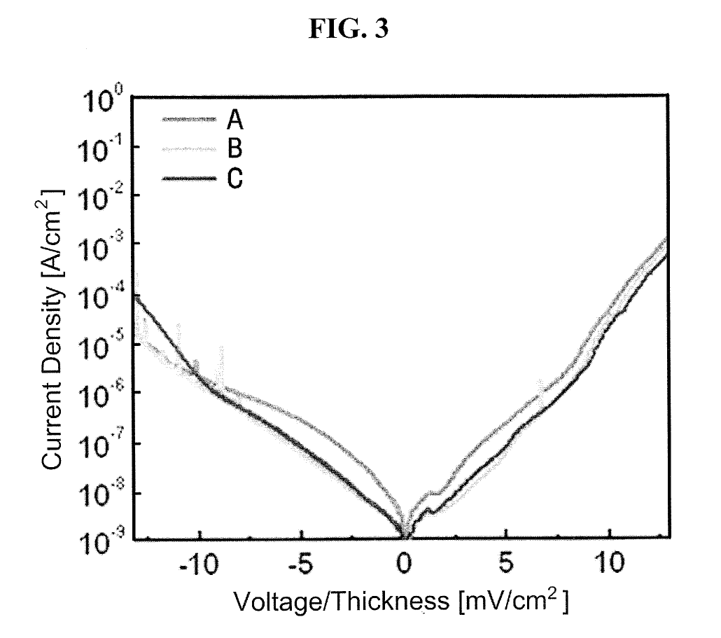

Reference is now made to FIG. 3, which is a graph illustrating a result obtained by experimentally measuring leakage current characteristics of flash memory devices according to some embodiments of charge-trap-type flash memory devices disclosed herein. The x-axis indicates voltage density (mV/cm), which may be obtained by dividing an application voltage by an equivalent oxide thickness. The y-axis indicates a current density. The amount of leakage current per unit area may be displayed, for example, on a log scale.

A normal read operation may be performed in a region of about ±5 volts on the x-axis and a write operation may be performed in a region of about ±10 volts on the x-axis.

Reference character A on the graph indicates the case where the blocking layer is only formed to constitute a single layer, reference character B on the graph indicates the case where the lower buffer layer and the blocking layer are formed, and reference character C on the graph indicates the case where the upper/lower buffer layers and the blocking layer are formed.

In some embodiments, in the case of A, the blocking layer may formed to include a thickness of about 300 Å using LaHfO₃. In the case of B, the lower buffer layer may be formed to include a thickness of about 25 Å using Al₂O₃ and the blocking layer may be formed to include a thickness of about 250 Å using LaHfO₃. In the case of C, each of the upper/lower buffer layers may be formed to include a thickness of about 25 Å using Al₂O₃ and the blocking layer may be formed to include a thickness of about 200 Å using LaHfO₃. In the three cases, since the equivalent oxide thickness (EOT) is respectively 153 Å, 150 Å, and 149 Å, the thickness difference may be ignored. In all of the three cases, an experiment was conducted in a state where the TaN layer was formed on the gate electrode.

When the blocking layer only is formed (the case of A), the amount of leakage current may be large in the read operation region. In the operation region (−10) where the stored information is erased, the amount of leakage current may be similar to those of the other embodiments. However, the operation region (+10) where the information is stored may be included and the amount of leakage current may be large.

For embodiments in which the lower buffer layer is formed (the case of B) and in which the upper/lower buffer layers are formed (the case of C), the amount of leakage current may be substantially the same in the read operation region and the write operation region and may be small.

According to experimental results, if at least one of the upper/lower buffer layers is formed together with the blocking layer, the amount of leakage current may be drastically reduced, and, thus, it may be possible to improve the data retention and/or the data write of the flash memory device. The preferable forming conditions of the buffer layers and the blocking layer can be derived by further researching methods of forming the buffer layers and the blocking layer and optimizing the same.

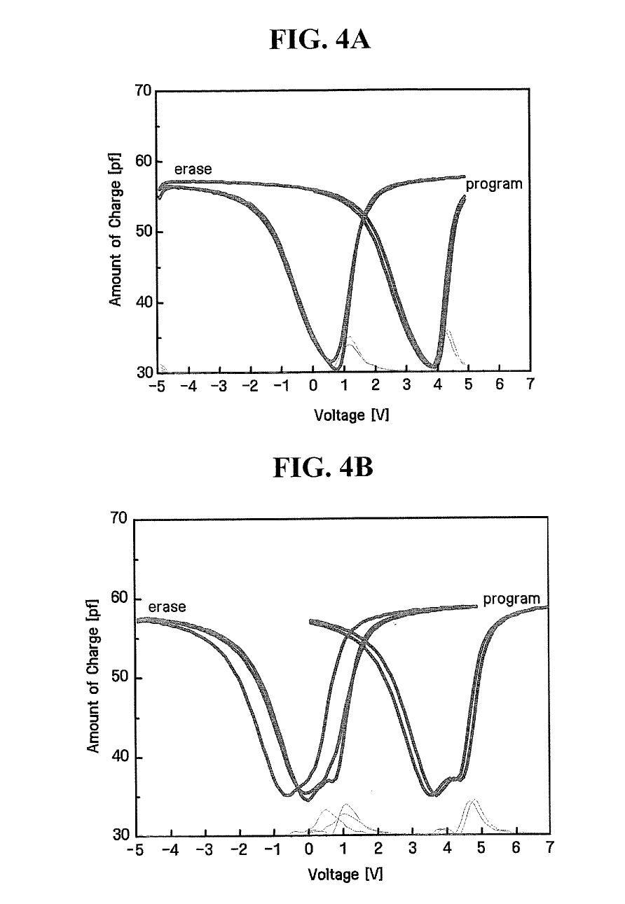

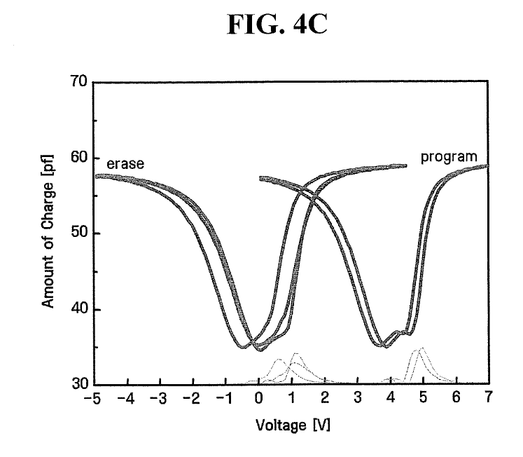

Reference is now made to FIGS. 4A to 4C, which are graphs illustrating the results that obtained by experimentally measuring charge trap characteristics of charge trap layers in flash memory devices according to some embodiments of charge-trap-type flash memory devices as disclosed herein.

If a voltage is applied to a gate electrode of the charge-trap-type flash memory device in a read operation state, voltages may be measured in a state where an inversion is generated in the channel region according to the amount of charges trapped in the charge trap layer. The measured voltages are compared.

The x-axis indicates a voltage (V) applied to a gate electrode and the y-axis indicates capacitance between the gate electrode and a channel region. The capacitance between the gate electrode and the channel region may indicate the amount of charges trapped in the charge trap layer according to the voltage as well as the charge inversion of the channel region according to the voltage.

The voltage applied to the gate electrode at which a maximum inversion peak is formed may be changed according to the amount of charges that are trapped in the charge trap layer. Specifically, when the amount of charges trapped and maintained in the charge trap layer is increased, the interval between the two graphs may be increased. When the amount of charges stored in the charge trap layer is increased, the inversion peak that is generated by the trapped charges moves to the right. When there is no charge stored in the charge trap layer, the inversion peak may be theoretically located at 0. However, since the condition where there is no charge trapped in the charge trap layer may exist very infrequently, the inversion peak may indicate an inversion voltage of about 1 V in accordance with an experimental result.

From the experimental result, it can be understood that the interval between the inversion peak voltage in the information storage state (for example, data 1) and the inversion peak voltage in the information deletion state (for example, data 0) may be wide. Specifically, when the interval between the two inversion peak voltages is wide, it may be determined whether information stored in each cell of the flash memory device is 1 or 0.

Reference is now made to FIG. 4A, which is a graph illustrating characteristics when a flash memory device according to some embodiments performs a read operation according to the amount of trapped charges in the case where a single blocking layer is formed of a lanthanum-containing compound (for example, LaHfO₃). In some embodiments, if the thickness of the single blocking layer is converted into an equivalent oxide thickness, the thickness may be approximately 154 Å. The inversion peak in a state where the information is stored may be about 4.3 V and the inversion peak in a state where the information is erased may be about 1.2 V. Thus, the operation window of the flash memory device may become 4.3−1.2=3.1 V.

Reference is now made to FIG. 4B, which is a graph illustrating characteristics when a flash memory device according to some embodiments performs a read operation according to the amount of trapped charges in the case where a blocking layer is formed of a lanthanum-containing compound and a lower buffer layer is formed of an aluminum oxide layer. In some embodiments, if the thickness of the lower buffer layer and the blocking layer is converted into the equivalent oxide thickness, the thickness may be approximately 150 Å. The inversion peak in a state where the information is stored may be about 4.9 V and the inversion peak in a state where the information is erased may be about 1.1 V. Thus, the operation window of the flash memory device may become 4.9−1.1=3.8 V.

Reference is now made to FIG. 4C, which is a graph illustrating characteristics when a flash memory device according to some embodiments performs a read operation according to the amount of trapped charges in the case where a blocking layer is formed of a lanthanum-containing compound and upper/lower buffer layers are formed of an aluminum oxide layer. In some embodiments, if the thickness of the upper/lower buffer layers and the blocking layer is converted into the equivalent oxide thickness, the thickness may be approximately 149 Å. The inversion peak in a state where the information is stored may be about 5 V, and the inversion peak in a state where the information is deleted may be about 1 V. Thus, the operation window of the flash memory device may become 5−1=4 V.

According to experimental results, better element characteristics may be obtained in the case where the lower buffer layer is formed of an aluminum oxide layer (refer to FIG. 4B) than the case where the single blocking layer is formed of a lanthanum-containing compound (refer to FIG. 4A). Even better element characteristics may be obtained in the case where both the upper buffer layer and the lower buffer layer are formed (refer to FIG. 4C). In theory, the experimental results are based on the fact that the amount of charges tunneled from the gate electrode to the charge trap layer may be small and the amount of charges leaking from the charge trap layer to the gate electrode and/or the channel region may be small.

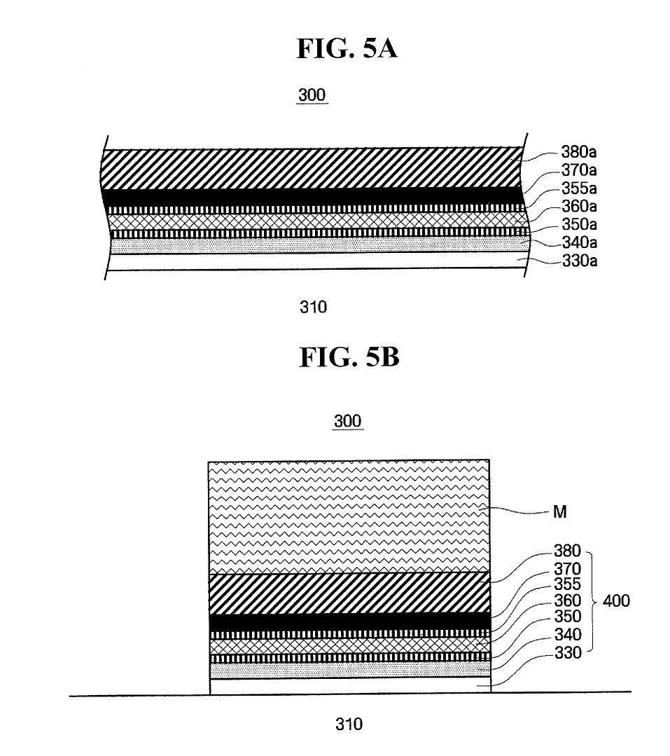

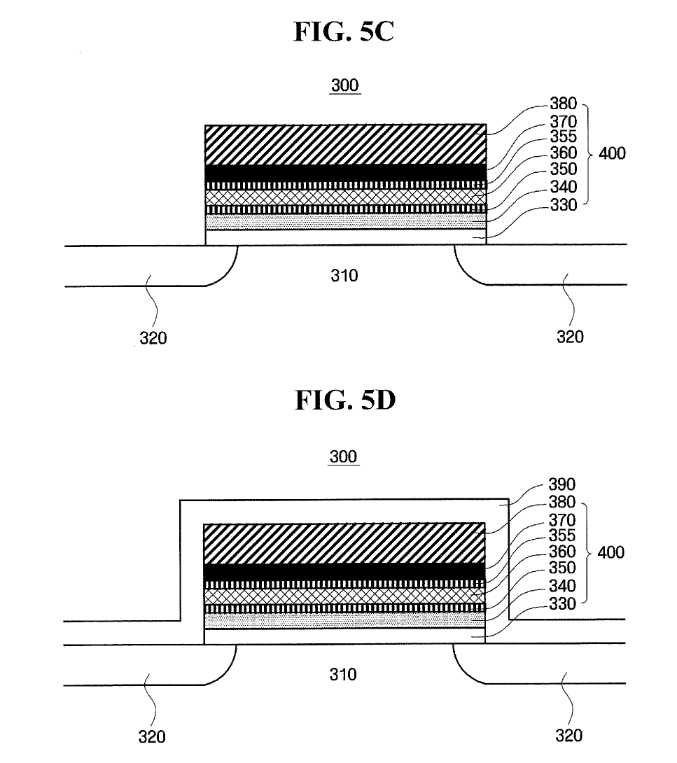

Reference is now made to FIGS. 5A to 5D, which are schematic diagrams illustrating methods of manufacturing a charge-trap-type flash memory device according to some embodiments of the present invention. Referring to FIG. 5A, the tunnel insulator 330a, the charge-storage layer 340a, the lower buffer layer 350a, the blocking layer 360a, the upper buffer layer 355a, the first gate electrode 370a, and/or the second gate electrode 380a may be sequentially formed on the substrate 310.

As described above, the substrate 310 may use various semiconductor element manufacturing substrates, including a silicon substrate, a silicon-germanium substrate, an SOI substrate and/or an SOS substrate, among others. The tunnel insulator 330a may be formed on the substrate 310. In some embodiments, the tunnel insulator 330a may be formed of a silicon oxide layer (SiₓO_{y}). In some embodiments, the tunnel insulator 330a may be formed by oxidizing the surface of the substrate 310 and/or by depositing a silicon oxide layer.

In some embodiments, the charge-storage layer 340a may be formed on the tunnel insulator 330a. The charge-storage layer 340a may be called a charge trap layer in a charge-trap-type flash memory device. In some embodiments, the charge trap layer may be formed of a silicon nitride layer (SiₓN_{y}). In some embodiments, the charge trap layer 340a may be formed of various insulating compounds, including SiₓO_{y}, HfO₂, ZrO₂, Ta₂O₅, HfAlO, HfZrO, HfSiO, AlN, and/or AlGaN, among others. In some embodiments, the charge-storage layer 340a may be called a floating gate in a floating-gate-typed flash memory device. In some embodiments, the floating gate may be formed of a conductive silicon layer.

After forming the floating gate 340a using the silicon layer, an ion implantation process may be performed, after which subsequent processes may be performed.

In some embodiments, the lower buffer layer 350a may be formed on the charge-storage layer 340a. The lower buffer layer 350a may be formed using materials including Al₂O₃, HfO₂, ZrO₂, and/or Sc₂O₃, among others. In some embodiments, the lower buffer layer 350a is formed of an aluminum oxide layer Al₂O₃.

In some embodiments, the blocking layer 360a may be formed on the lower buffer layer 350a. The blocking layer 360a may be formed of a lanthanum-containing compound, and in some embodiments, a ternary lanthanum compound. Specifically, the blocking layer 360a may be formed of various compounds including LaHfO₃, LaAlO₃, LaOₓ, DyScO₃, GdScO₃, Dy₂O₃, PrOₓ, and/or NdOₓ, among others.

The upper buffer layer 355a may be formed on the blocking layer 360a. In some embodiments, the upper buffer layer 355a may be formed of the same material as the lower buffer layer 350a.

In some embodiments, the first gate electrode 370a may be formed on the upper buffer layer 355a. In some embodiments, the first gate electrode 370a maybe formed of a metal compound. For example, some embodiments provide that the first gate electrode 370a may be formed of a tantalum compound including a tantalum nitride layer and/or a tantalum oxide layer, among others.

The second gate electrode 380a may be formed on the first gate electrode 370a. In some embodiments, the second gate electrode 380a may be formed of a silicon layer, among others.

Referring to FIG. 5B, an etching mask M may be formed and a gate structure 400 that includes the second gate electrode 380, the first gate electrode 370, the upper buffer layer 355, the blocking layer 360, the lower buffer layer 350, the charge-storage layer 340, and/or the tunnel insulator 330, may be formed via an etching process. In some embodiments, the etching mask M may be formed of a photoresist pattern. In some embodiments, after forming a hard mask using a silicon nitride layer and/or a silicon oxynitride layer, the photoresist pattern may be used to form the etching mask M. Specifically, the etching mask M may be formed of a single material layer and/or multi-layered material layers. Subsequently, the etching mask M may be removed.

Referring to FIG. 5C, the junction regions 320 may be formed via an ion implantation process. The ion implanting process may be a process during which elements of Group 3 and/or 5 of the Periodic Table of Elements are implanted in an ionic state. In some embodiments, the ion implantation process may be performed by an ion beam implantation method and/or a plasma doping method, among others.

Before performing the ion implantation process, an ion implantation buffer layer (not shown) may be formed on a region where an ion needs to be implanted. In some embodiments, the ion implantation buffer layer may be formed of a silicon oxide layer. The ion implantation buffer layer may compensate for the surface damage of the layers in which ions are implanted.

When the ions are implanted to form the junction regions 320, the ions may be implanted into the second gate electrode 380, which may make the electrode conductive. In this regard, the ion implantation buffer layer may be formed on the second gate electrode 380.

Referring to FIG. 5D, the capping layer 390 that caps the gate structure 400 may be formed. In some embodiments, the capping layer 390 may be formed by depositing a silicon oxide layer. The capping layer 390 may extend to the substrate 310 and may be partially formed on the junction regions 320. In some embodiments, contact plugs (not shown) that are electrically connected to the junction regions 320 may be selectively formed.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A flash memory device comprising:
a tunnel insulator on a substrate;
a charge-storage layer on the tunnel insulator;
a lower buffer layer, comprising a silicon-free insulator, on the charge-storage layer;
a blocking layer, comprising oxides or ternary lanthanum compounds, wherein the oxides or ternary lanthanum compounds comprise lanthanide elements, on the lower buffer layer;
a first gate electrode on the blocking layer; and
a second gate electrode on the first gate electrode.

2. The flash memory device of claim 1, wherein the lower buffer layer comprises any of HfO₂, ZrO₂, Sc₂O₃, and/or Al₂O₃.

3. The flash memory device of claim 1, wherein the oxides or ternary lanthanum compounds further comprise any of LaHfO₃, LaAlO₃, LaOs, DyScO₃, GdScO₃, Dy₂O₃, PrOsₓ, and/or NdOₓ.

4. The flash memory device of claim 1, further comprising:
an upper buffer layer formed between the blocking layer and the first gate electrode.

5. The flash memory device of claim 4, wherein the upper buffer layer comprises any of HfO₂, ZrO₂, Sc₂O₃, and/or Al₂O₃.

6. The flash memory device of claim 1, wherein the charge-storage layer comprises an insulator that is formed of any of SiₓN_{y}, SiₓO_{y}, HfO₂, ZrO₂, Ta₂O₅, HfAlO, HfZrO, HfSiO, AlN, and/or AlGaN.

7. The flash memory device of claim 1, wherein the charge-storage layer comprises a conductive silicon layer.

8. The flash memory device of claim 1, wherein the first gate electrode comprises a tantalum compound.

9. The flash memory device of claim 1, wherein the second gate electrode comprises conductive silicon.

10. The flash memory device of claim 1, further comprising an insulating capping layer formed on the second gate electrode.

11. A method of manufacturing a flash memory device, comprising:
forming a tunnel insulator on a substrate;
forming a charge-storage layer on the tunnel insulator;
forming a lower buffer layer, comprising a silicon-free insulator, on the charge-storage layer;
forming a blocking layer, comprising oxides and/or ternary lanthanum compounds comprising lanthanide elements, on the lower buffer layer;
forming a first gate electrode on the blocking layer; and
forming a second gate electrode on the first gate electrode.

12. The method of claim 11, wherein the lower buffer layer comprises any of HfO₂, ZrO₂, SC₂O₃, and/or Al₂O₃.

13. The method of claim 11, wherein the oxides and/or ternary lanthanum compounds comprise any of LaHfO₃, LaAlO₃, LaOₓ, DyScO₃, GdScO₃, Dy₂O₃, PrOₓ, and/or NdOₓ.

14. The method of claim 11, further comprising:
forming an upper buffer layer between the blocking layer and the first gate electrode.

15. The method of claim 14, wherein the upper buffer layer comprises any of HfO₂, ZrO₂, Sc₂O₃, and/or Al₂O₃.

16. The method of claim 11, wherein the charge-storage layer comprises an insulating layer and any of SiₓN_{y}, SiₓO_{y}, HfO₂, ZrO₂, Ta₂O₅ HfAlO, HfzrO, HfsiO, AlN, and/or AlGaN.

17. The method of claim 11, wherein the charge-storage layer comprises a conductive silicon layer.

18. The method of claim 11, wherein the first gate electrode comprises a tantalum compound.

19. The method of claim 11, wherein the second gate electrode comprises conductive silicon.

20. The method of claim 11, further comprising:
forming an insulating capping layer on the second gate electrode.
